(19) United States
(12) Patent Application Publication
(10) Pub. No.: US 2007/0079932 A1
(43) Pub. Date: Apr. 12, 2007

(54) DIRECTED PURGE FOR CONTACT FREE DRYING OF WAFERS

(75) Inventors: VICTOR MIMKEN, Boise, ID (US); YONGQIANG LU, Meridian, ID (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/460,049

(22) Filed: Jul. 26, 2006

Related U.S. Application Data
(63) Continuation-in-part of application No. 10/826,458, filed on Apr. 16, 2004.
Application No. 10/826,458 is a continuation of application No. 10/010,240, filed on Dec. 7, 2001, now Pat. No. 6,726,848.
(60) Provisional application No. 60/703,259, filed on Jul. 27, 2005.
(60) Provisional application No. 60/702,901, filed on Jul. 26, 2005.

(51) Int. Cl. H01L 21/306

(52) U.S. Cl. 156/345.11; 156/345.51

(57) ABSTRACT

The present invention generally provides a method and apparatus for processing a substrate in a wet processing chamber. One embodiment of the present invention provides an apparatus for processing a substrate. The apparatus comprises a gas delivery assembly disposed outside the chamber. The gas delivery assembly directs a gas flow towards areas where a substrate support contacts the substrate.

### CROSS-REFERENCE TO RELATED APPLICATIONS:

This application claims benefit of United States Provisional Patent Application No. 60/703,259 (Attorney Docket No. 010430L), filed Jul. 27, 2005, and U.S. Provisional Patent Application Ser. No. 60/702,901 (Attorney Docket No. 010435L) filed Jul. 26, 2005, which are incorporated herein by reference. This application is a continuation-in-part of co-pending U.S. patent application Ser. No. 10/826,458 (Attorney Docket No. 010533.C1), filed Apr. 16, 2004, which published as U.S. Patent Publication No. 2004/0198051 on Oct. 7, 2004, which is a continuation of U.S. patent application Ser. No. 10/010,240 (Attorney Docket No. 10533), filed Dec. 7, 2001, which issued as U.S. Pat. No. 6,726,848 on Apr. 27, 2004, both of which are incorporated by reference herein.

### BACKGROUND OF THE INVENTION

1. Field of the Invention

This application relates to single substrate processing. More specifically, this application provides methods and apparatus for cleaning a substrate in a cleaning solution.

2. Description of the Related Art

Substrate surface preparation and cleaning is an essential step in the semiconductor manufacturing process. Multiple cleaning steps can be performed. The process recipe may include etch, clean, rinse, and dry steps. The combination is referred to as wet bench processing. Wet bench processing is often performed upon batches of substrates housed in a cassette. The cassette is exposed to a variety of process and rinse chemicals in multiple vessels. The vessel may have piezoelectric transducers to propagate megasonic energy into the vessel's cleaning solution. The megasonic energy enhances cleaning by inducing microcavitation in the cleaning solution, helping to dislodge particles off of the substrate surfaces. Drying the substrate is performed after the wet bench processing and is facilitated by using isopropyl alcohol in a rinse solution.

An alternative tool for this process provides a number of the process steps in one vessel upon a batch of substrates. The one vessel batch tool eliminates substrate transfer steps, has a reduction in fabrication facility footprint size, and reduces the risk of breakage and particle contamination. A one vessel individual substrate tool has also been developed. Thus, a mechanism for improved drying of the substrate as it is removed from the processing tool is needed.

### SUMMARY OF THE INVENTION

The present invention generally provides a method and apparatus for processing a substrate in a wet processing chamber.

One embodiment of the present invention provides an apparatus for processing a substrate. The apparatus comprises a chamber having an upper opening, a lower process volume and an upper process volume, wherein the lower process volume is configured to retain a processing fluid, a transfer assembly configured to transfer the substrate in and out the chamber through the upper opening, and a gas delivery assembly disposed outside the chamber near the upper opening.

Another embodiment of the present invention provides an apparatus for processing a substrate. The apparatus comprises a vertical immersing chamber having an upper opening configured to retain a processing liquid therein, a transfer assembly configured to transfer the substrate in and out the vertical immersing chamber through the upper opening, the transfer assembly having one or more substrate receiving areas, and a gas delivery assembly positioned adjacent the upper opening and configured to direct a gas flow towards the substrate receiving areas of the transfer assembly.

Yet another embodiment of the present invention provides a method for processing a substrate. The method comprises introducing the substrate into a chamber through an upper opening of the chamber using a transfer assembly, wherein the chamber retains a processing liquid in a lower processing volume, immersing the substrate to the processing liquid, removing the substrate from the chamber using the transfer assembly, and exposing the substrate to a gas flow delivered from a nozzle positioned outside the chamber near the upper opening.

Yet another embodiment of the present invention provides a method for processing a substrate. The method comprises introducing the substrate into a chamber through an upper opening of the chamber using a transfer assembly having an end effecter configured to support and receive the substrate, wherein the chamber retains a processing liquid in a lower processing volume, immersing the substrate to the processing liquid, removing the substrate from the chamber using the transfer assembly, exposing the substrate to a gas flow delivered from a nozzle positioned near a path of the end effecter.

### BRIEF DESCRIPTION OF THE DRAWINGS

FIG. 1 illustrates a cross sectional view of a substrate processing chamber in accordance with one embodiment of the present invention.

FIG. 2 illustrates a partial cross sectional view of the substrate processing of FIG. 1 in a different processing position.

FIG. 3A illustrates a perspective view of an end effecter in accordance with one embodiment of the present invention.

FIG. 3B illustrates a sectional view of the end effecter of FIG. 3A.

FIG. 3C illustrates a partial side view of the end effecter of FIG. 3A.

FIG. 4A illustrates a perspective view of an end effecter in accordance with one embodiment of the present invention.

FIG. 4B illustrates a sectional view of the end effecter of FIG. 4A.

FIG. 4C illustrates a partial side view of the end effecter of FIG. 4A.

### DETAILED DESCRIPTION

The present invention relates to embodiments of chambers for processing a single substrate and associated processes with embodiments of the chambers. The chambers and methods of the present invention may be configured to perform wet processing processes, such as for example etching, cleaning, rinsing and/or drying a single substrate. Similar processing chambers may be found in U.S. Pat. No. 6,726,848 and U.S. patent application Ser. No. 11/445,707, filed Jun. 2, 2006, which are incorporated herein by reference.

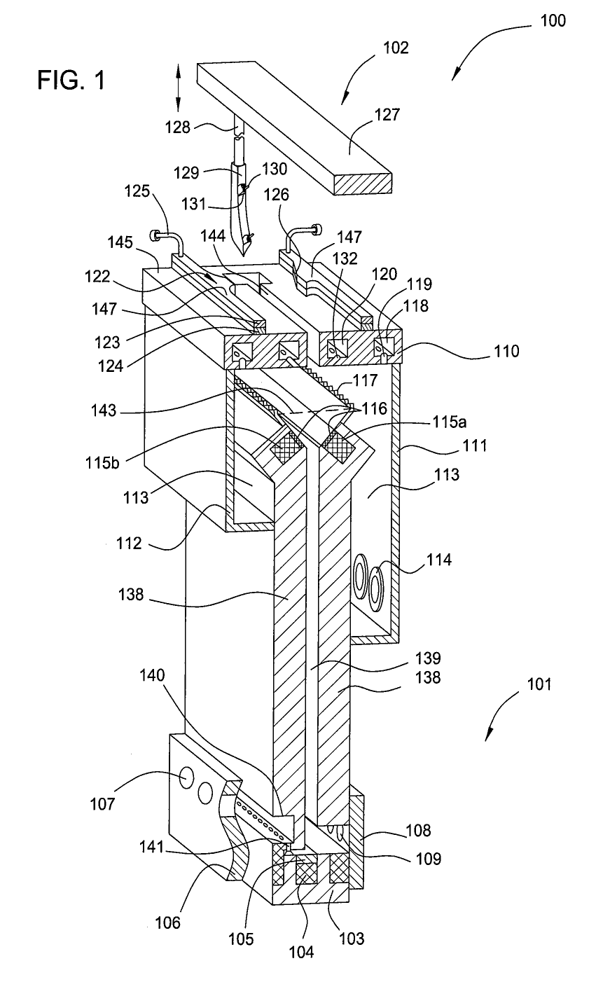

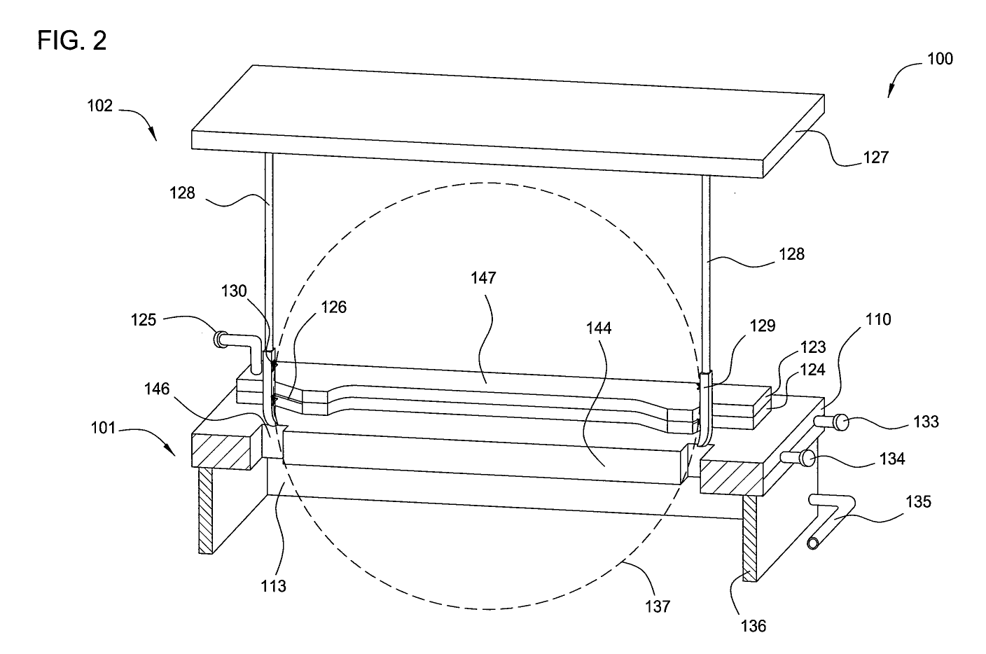

FIG. 1 illustrates a cross sectional view of a substrate processing chamber 100 in accordance with one embodiment of the present invention. FIG. 2 illustrates a partial cross sectional view of the substrate processing of FIG. 1 in a different processing position. The substrate processing chamber 100 comprises a chamber body 101 configured to retain a liquid and/or a vapor processing environment and a substrate transfer assembly 102 configured to transfer a substrate in and out the chamber body 101.

The lower portion of the chamber body 101 generally comprises side walls 138 and a bottom wall 103 defining a lower processing volume 139. The lower processing volume 139 may have a rectangular shape configured to retain fluid for immersing a substrate therein. A weir 117 is formed on top of the side walls 138 to allow fluid in the lower processing volume 139 to overflow. The upper portion of the chamber body 101 comprises overflow members 111 and 112 configured to collect fluid flowing over the weir 117 from the lower processing volume 139. The upper portion of the chamber body 101 further comprises a chamber lid 110 having an opening 144 formed therein. The opening 144 is configured to allow the substrate transfer assembly 102 to transfer at least one substrate in and out the chamber body 101.

An inlet manifold 140 configured to fill the lower processing volume 139 with processing fluid is formed on the sidewall 138 near the bottom of the lower portion of the chamber body 101. The inlet manifold 140 has a plurality of apertures 141 opening to the bottom of the lower processing volume 139. An inlet assembly 106 having a plurality of inlet ports 107 is connected to the inlet manifold 140. Each of the plurality of inlet ports 107 may be connected with an independent fluid source, such as chemicals for etching, cleaning, and Dl water for rinsing, such that different fluids or combination of fluids may be supplied to the lower processing volume 139 for different processes.

During processing, processing fluid may flow in from one or more of the inlet ports 107 to fill the lower processing volume 139 from bottom via the plurality of apertures 141. In one embodiment, the lower processing volume 139 may be filled in less than about 10 seconds, for example less than about 5 seconds, such as between about 5 seconds and about 1 second.

As the processing fluid fills up the lower processing volume 139 and reaches the weir 117, the processing fluid overflows from the weir 117 to an upper processing volume 113 and is connected by the overflow members 111 and 112. A plurality of outlet ports 114 configured to drain the collected fluid may be formed on the overflow member 111. The plurality of outlet ports 114 may be connected to a pump system. In one embodiment, each of the plurality of outlet ports 114 may form an independent drain path dedicated to a particular processing fluid. In one embodiment, each drain path may be routed to a negatively pressurized container to facilitate removal, draining and/or recycling of the processing fluid. In one embodiment, the overflow member 112 may be positioned higher than the overflow member 111 and fluid collected in the overflow member 112 may flow to the overflow member 111 through a conduit 135 (shown in FIG. 2).

In one embodiment, a draining assembly 108 may be coupled to the sidewall 138 near the bottom of the lower processing volume 139 and in fluid communication with the lower processing volume 139. The draining assembly 108 is configured to drain the lower processing volume 139 rapidly. In one embodiment, the draining assembly 108 has a plurality of draining ports 109, each configured to form an independent draining path dedicated to a particular processing fluid. In one embodiment, each of the independent draining path may be connected to a negatively pressurized sealed container for fast draining of the processing fluid in the lower processing volume 139. Similar fluid supply and draining configuration may be found in FIGS. 9-10 of U.S. patent application Ser. No. 11/445,707, filed Jun. 2, 2006, which is incorporated herein by reference.

In one embodiment, a megasonic transducer 104 is disposed behind a window 105 in the bottom wall 103. The megasonic transducer 104 is configured to provide megasonic energy to the lower processing volume 139. The megasonic transducer 104 may comprise a single transducer or an array of multiple transducers, oriented to direct megasonic energy into the lower processing volume 139 via the window 105. When the megasonic transducer 104 directs megasonic energy into processing fluid in the lower processing volume 139, acoustic streaming, i.e. streams of micro bubbles, within the processing fluid may be induced. The acoustic streaming aids the removal of contaminants from the substrate being processed and keeps the removed particles in motion within the processing fluid hence avoiding reattachment of the removed particles to the substrate surface.

In one embodiment, a pair of megasonic transducers 115a, 115b, each of which may comprise a single transducer or an array of multiple transducers, are positioned behind windows 116 at an elevation below that of the weir 117, and are oriented to direct megasonic energy into an upper portion of lower processing region 139. The transducers 115a and 115b are configured to direct megasonic energy towards a front surface and a back surface of a substrate respectively.

The transducers 115a and 116b are preferably positioned such that the energy beam interacts with the substrate surface at or just below a gas/liquid interface (will be described below), e.g. at a level within the top 0-20% of the liquid in the lower processing volume 139. The transducers may be configured to direct megasonic energy in a direction normal to the substrate surface or at an angle from normal. Preferably, energy is directed at an angle of approximately 0-30 degrees from normal, and most preferably approximately 5-30 degrees from normal. Directing the megasonic energy from the transducers 115a and 115b at an angle from normal to the substrate surface can have several advantages. For example, directing the energy towards the substrate at an angle minimizes interference between the emitted energy and return waves of energy reflected off the substrate surface, thus allowing power transfer to the solution to be maximized. It also allows greater control over the power delivered to the solution. It has been found that when the transducers are parallel to the substrate surface, the power delivered to the solution is highly sensitive to variations in the distance between the substrate surface and the transducer. Angling the transducers 115a and 115b reduces this sensitivity and thus allows the power level to be tuned more accurately. The angled transducers are further beneficial in that their energy tends to break up the meniscus of fluid extending between the substrate and the bulk fluid (particularly when the substrate is drawn upwardly through the band of energy emitted by the transducers)-thus preventing particle movement towards the substrate surface.

Additionally, directing megasonic energy at an angle to the substrate surface creates a velocity vector towards the weir 117, which helps to move particles away from the substrate and into the weir 117. For substrates having fine features, however, the angle at which the energy propagates towards the substrate front surface must be selected so as to minimize the chance that side forces imparted by the megasonic energy will damage fine structures.

It may be desirable to configured the transducers 115a and 115b to be independently adjustable in terms of angle relative to normal and/or power. For example, if angled megasonic energy is directed by the transducer 115a towards the substrate front surface, it may be desirable to have the energy from the transducer 115b propagate towards the back surface at a direction normal to the substrate surface. Doing so can prevent breakage of features on the front surface by countering the forces imparted against the front surface by the angled energy. Moreover, while a relatively lower power or no power may be desirable against the substrate front surface so as to avoid damage to fine features, a higher power may be transmitted against the back surface (at an angle or in a direction normal to the substrate). The higher power can resonate through the substrate and enhance microcavitation in the trenches on the substrate front, thereby helping to flush impurities from the trench cavities.

Additionally, providing the transducers 115a, 115b to have an adjustable angle permits the angle to be changed depending on the nature of the substrate (e.g. fine features) and also depending on the process step being carried out. For example, it may be desirable to have one or both of the transducers 115a, 115b propagate energy at an angle to the substrate during the cleaning step, and then normal to the substrate surface during the drying step (see below). In some instances it may also be desirable to have a single transducer, or more than two transducers, rather than the pair of transducers 115a, 115b.

The rotational alignment of the substrate prior to entry into the substrate processing chamber 100 may also be selected to reduce damage to features on the device. The flow of fluid through the lower processing volume 139 during megasonic cleaning applies a force on the features and the force can be substantially reduced by orienting the substrate in a direction most resistant to the force. For many substrates the direction most resistant to the force is 45 degrees from a line parallel to sidewalls 138 of features that may be damaged by the force. However, the direction most resistant to the force can be 90 degrees if all sidewalls that may be damaged are aligned in one direction.

In one embodiment, the chamber lid 110 may have integrated vapor nozzles 121 and exhaust ports 119 for supplying and exhausting one or more vapor into the upper processing volume 113. During process, the lower processing volume 139 may be filled with a processing liquid coming in from the inlet manifold 140 and the upper processing volume 113 may be filled with a vapor coming in from the vapor nozzles 121 on the chamber lid 110. A liquid vapor interface 143 may be created in the chamber body 101. In one embodiment, the processing liquid fills up the lower processing volume 139 and overflows from the weir 117 and the liquid vapor interface 143 is located at the same level as the wire 117.

During process, a substrate being processed in the substrate processing chamber 100 is first immerged in the processing liquid in the lower processing volume 139, and then pulled out of the processing liquid. It is desirable that the substrate is free of the processing liquid after being pulled out of the lower processing volume 139. In one embodiment, the Marangoni effect, i.e. the presence of a gradient in surface tension will naturally cause the liquid to flow away from regions of low surface tension, is used to remove the processing liquid from the substrate. The gradient in surface tension is created at the liquid vapor interface 143. In one embodiment, an isopropyl alcohol (IPA) vapor is used to create the liquid vapor interface 143. When the substrate is being pulled out from the processing liquid in the lower processing volume 139, the IPA vapor condenses on the liquid meniscus extending between the substrate and the processing liquid. This results in a concentration gradient of IPA in the meniscus, and results in so-called Marangoni flow of liquid from the substrate surface.

As shown in FIG. 1, the opening 144, which is configured to allow the substrate transfer assembly 102 in and out the chamber body 101, is formed near a center portion of the chamber lid 110. The vapor nozzles 121 are connected to a pair of inlet channels 120 formed on either side of the opening 144 in the chamber lid 110. In one embodiment, the vapor nozzles 121 may be formed in an angle such that the vapor is delivered towards the substrate being processed. The exhaust ports 119 are connected to a pair of exhaust channels 118 formed on either side of the opening 144. Shown in FIG. 2, each of the inlet channels 120 may be connected to an inlet pipe 134 extending from the chamber lid 110. The inlet pipes 134 may be further connected to a vapor source. In one embodiment, the vapor nozzles 121 may be used to supply a gas, such as nitrogen, to the upper processing volume 113. Each of the exhaust channels 118 may be connected to an exhaust pipe 133 extending from the chamber lid 110. The exhaust pipes 133 may be further connected to a pump system for removing vapor from the upper processing volume 113.

Referring to FIG. 2, the substrate transfer assembly 102 comprises a pair of posts 128 connected to a frame 127. The frame 127 may be connected with an actuator mechanism configured to move the substrate transfer assembly 102 vertically. An end effecter 129 configured to receive and secure a substrate 137 by an edge is connected to a terminal end of each of the posts 128. Each of the end effecters 129 is configured to provide lateral and radial support to the substrate 137 while the substrate transfer assembly 102 moves the substrate 137 to and from the chamber body 101. In one embodiment, two pairs of rod members 130 may be extended from the end effecter 129 to provide lateral support to the substrate 137 and a groove 131 formed between each pair of the rod members 130 may be configured to provide radial support to the substrate 137. In one embodiment, the top pair of rod members 130 of each end effecter 129 is positioned on the same level and the straight line connecting the top pairs of rod members 130 is close to or passes the center of the substrate 137 being supported thereon. On each end effecter 129, the top pair and bottom pair of rod members 130 form an angle of about 20° with the center of the substrate as the vertex of the angle. In one embodiment, the opening 144 on the chamber lid 110 may have enlarged ends 146 to accommodate the end effectors 129.

After etching and/or rinsing a substrate in a process liquid in the lower processing volume 139 of the substrate processing chamber 100, the substrate is removed from the lower processing volume 139 across the liquid vapor interface 143 then out of the substrate processing chamber 100. During the removal process, the substrate surfaces may demonstrate hydrophilic properties which cause residual liquid on the substrate surface to flow traversely across the substrate surface, generally known as “streaking”. When the substrate is moved across the liquid vapor interface 143 in a particular speed, the Marangoni process may remove a majority of the processing liquid from the substrate surfaces. However, the residual processing liquid flow traversely across the substrate surface and retained around the contact area between the end effecters 129 contact the substrate. The residual liquid that migrates across the substrate is referred to as flashing and can extend up to 1 cm or more from the contact area between the substrate and end effecter.

In one embodiment, a purge gas may be used following the Marangoni process to remove any residual processing liquid on the substrate. A directed purge assembly 122 may be attached to an upper surface 145 of the chamber lid 110. The directed purge assembly 122 is configured to provide a gas flow to the substrate 137 as the substrate 137 is being removed from the substrate processing chamber 100. The residual fluid retained at the contact region between the end effecter and substrate is removed upon exposure to a gas flow delivered from the directed purge assembly 122. The residual fluid may be removed because of the pushing force from the gas flow and/or the drying effect of the gas flow. A variety of gases may be used for the gas flow, for example air, and non-reactive gases, such as nitrogen, argon, carbon dioxide, helium or the combination thereof. In one embodiment, the gas used in the gas flow may be heated to increase the drying effect.

The directed purge assembly 122 may comprise a pair of nozzle assemblies 147 each positioned on one side of the opening 144 and configured to provide a gas flow to one side of the substrate. Each of the nozzle assembly 147 comprises a bottom member 124 attached to the chamber lid 110 and an upper member 123 attached to the bottom member 124. An inlet port 125 may be connected to each nozzle assembly 147. One or more nozzles 126 in fluid communication with the inlet port 125 may be formed between the bottom member 124 and the upper member 123. The one or more nozzles 126 may be blade shaped, a drilled hole, or an engineered nozzle.

In one embodiment, as shown in FIG. 2, each nozzle assembly 147 may have two nozzles 126 positioned near each of the enlarged ends 146 of the opening 144. The two nozzles 126 may be oriented such that the gas is directed towards the contact area of the end effecter 129 and the substrate 137. In one embodiment, each of the two nozzles 126 may have a blade shape with a width of about 1 inch and a height of about 0.005 inch.

The gas flow from the nozzles 126 may have a flow rate in the range of about 5 liters per minute per nozzle to about 50 liters per minute per nozzle. In one embodiment, the gas flow rate is about 40 liters per minute per nozzle. When the substrate 137 is being removed from the chamber body 101, the distance between the nozzles 126 to the substrate 137 may be in the range of about 1 mm to about 50 mm. In one embodiment, the distance between the nozzles 126 to the substrate 137 may be about 15 mm. In another embodiment, the nozzles 126 may be movable so that the distance between the nozzles 126 and the substrate 137 is adjustable to suit different processing requirements. In one embodiment, the nozzles 126 may be oriented such that the gas flow from the nozzles 126 has an angle of about 15° from a surface of the substrate 137. In one embodiment, the gas flow delivered from the nozzles 126 may be horizontal, i.e. parallel to the upper surface 145 of the chamber lid 110.

In another embodiment, the directed purge assembly 122 may be positioned inside the chamber body 101 in the upper processing volume 113, for example, near the opening 144 above the liquid vapor interface 143.

In addition to using the Marangoni process and directed purge to remove undesirable processing liquid from the substrate after a substrate being processed in a wet processing chamber, such as the substrate processing chamber 100, limiting the contact area between the end effecter and the substrate being processed also reduces the likelihood of the processing liquid adhesion upon the substrate removal from the chamber. This is specifically desirable in the situation where the contact of end effecters with the substrate causes crevices that retain fluids and increase particle formation.

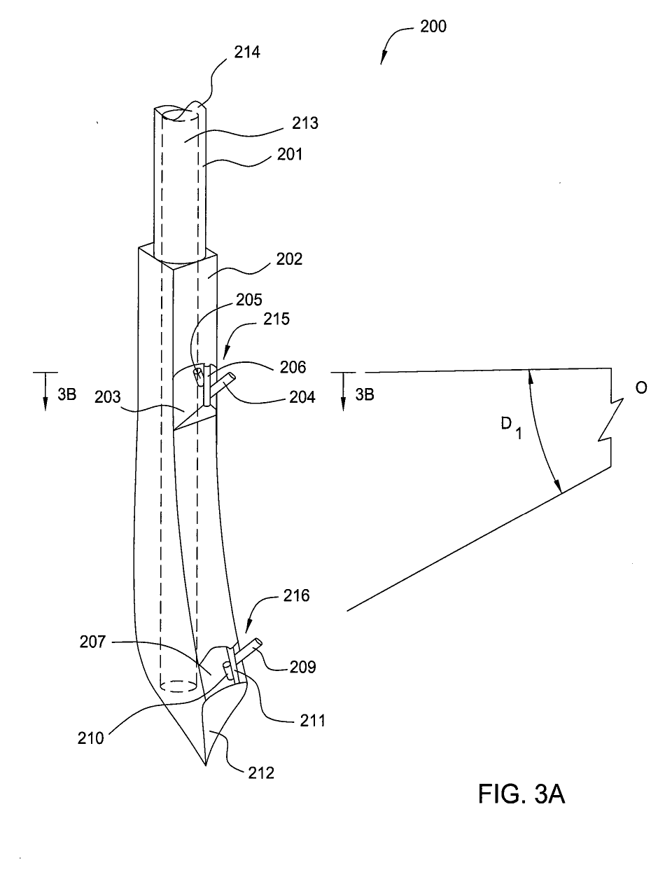

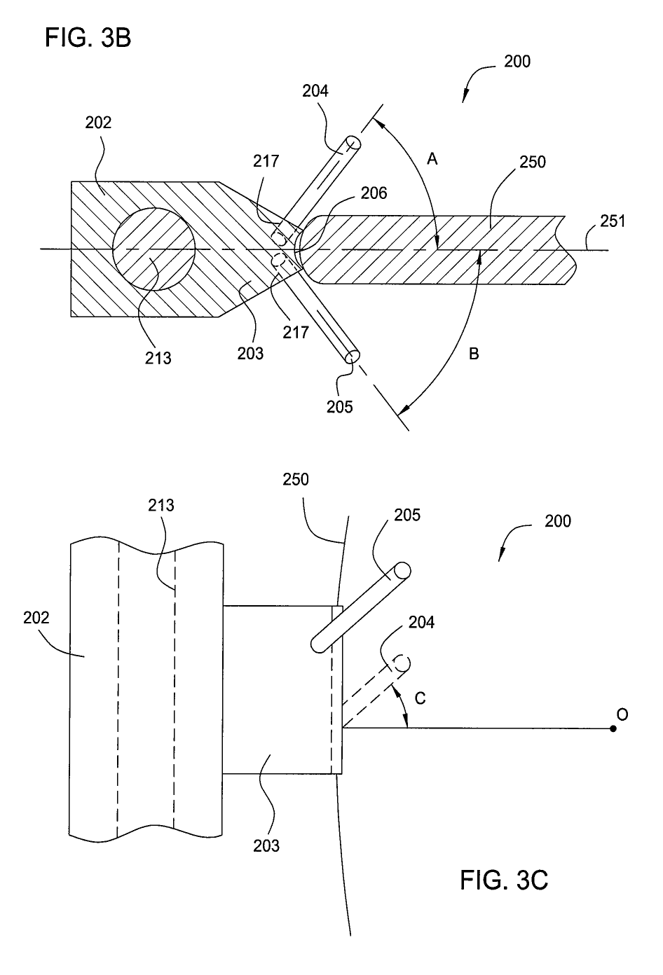

FIGS. 3A-3C illustrate one embodiment of an end effecter 200 having a reduced contact area with a substrate. FIG. 3A illustrates a perspective view of the end effecter 200 in accordance with one embodiment of the present invention. FIG. 3B illustrates a sectional view of the end effecter 200 of FIG. 3A. FIG. 3C illustrates a partial side view of the end effecter 200 of FIG. 3A. The end effect 200 may be used in pairs for receiving, supporting and transferring a substrate in a substrate processing system, such as the substrate processing system 100 shown in FIGS. 1 and 2.

The end effecter 200 generally comprises a post 201 configured to connect with a substrate transferring mechanism, such as the substrate transfer assembly 102 of the substrate processing system 100. The post 201 may comprise a core 213 made of a rigid material for support and a non-reactive coating 214 protecting the core 213 from processing fluid and vapor. The core 213 may be made from a rigid material, such as metals, for example stainless steel, and hastolloy. In one embodiment, the core 213 may be made from tungsten carbide (WC). The high rigidity of tungsten carbide affords small size for the core 213 which is desirable. The non-reactive coating 214 may be made from a polymer, such as perfluoroalkoxy (PFA).

A body 202 is formed on an end of the core 213. The core 213 provides rigid support to the body 202. In one embodiment, a hole may be machined with in the body 202 along nearly the entire length of the body 202 for accommodating the core 213 therein. Two sets of contact assemblies 215 and 216 configured to receive and support a substrate 250 (the substrate 250 is shown in FIGS. 3B and 3C) are formed on the body 202. In one embodiment, the body 202 may have a pointy end 212 near the bottom facilitating dripping of processing fluid. The body 202 may be made from a material resistive to processing fluids and vapors that may be used in the substrate processing system.

The body 202 may have a slightly curved shape and have two bases 203 and 207 formed on one side. In one embodiment, the bases 203 and 207 are positioned such that an angle Dl formed between the bases 203 and 207 with a vertex at the center O of a substrate being processed is about 20°. The contact assemblies 215 and 216 are formed on the bases 203 and 207 respectively.

The contact assembly 215 comprises rod members 204 and 205 extending from the base 203. A groove 206 is formed between rod members 204 and 205. As shown in FIG. 3B, the rod members 204 and 205 are secured in holes 217 formed in the base 203. In one embodiment, the rod members 204 and 205 are replaceable. The rod members 204 and 205 are positioned on opposite sides of the substrate 250 being processed providing guidance and light support to the substrate 250. The rod member 204 forms an angle A with a central plane 251 of the body 202 parallel to the substrate 250 and the rod member 205 forms an angle B with the central plane 251. In one embodiment, the angles A and B are about 45°.

Referring to FIG. 3C, the rod member 204 forms an angle C with a radius of the substrate 250 passing the base 203. In one embodiment, the angle C is about 45°. The rod member 205 forms about the same angle as angle C with the radius of the substrate 250 passing the base 203. The groove 206 may be machined to a depth that is similar to or less than the thickness of the substrate 250 being processed therein. In one embodiment, the groove 206 has a depth between about 0.015 inch and about 0.030 inch. The groove 206 is configured to provide radial support to the substrate 250 with minimal contact to the substrate.

Similarly, the contact assembly 216 comprises rod members 209 and 210 extending from the base 207. A groove 211 is formed between rod members 209 and 210. The rod members 209 and 210 are secured in holes formed in the base 207. The rod members 209 and 210 are positioned on opposite sides of the substrate 250 being processed providing guidance and light support to the substrate 250. The rod members 209 and 210 also form similar compound angles with the substrate as the rod members 204 and 205. The groove 211 may be machined to a depth that is similar to or less than the thickness of the substrate 250 being processed therein. The groove 211 has a depth between about 0.015 inch and about 0.030 inch. The groove 211 is configured to provide radial support to the substrate 250 with minimal contact to the substrate.

The body 202 and the rod members 204, 205, 209 and 210 may be made from material that is resistive to processing liquids and vapors, does not scratch the substrate being processed, and good particle performance. In one embodiment, the body 202 and the rod members 204, 205, 209 and 210 may be made from a polymer, such as PFA, or TEFLON® polymer. In one embodiment, the rod members 204, 205, 209 and 210 may have a diameter of about 0.062 inch.

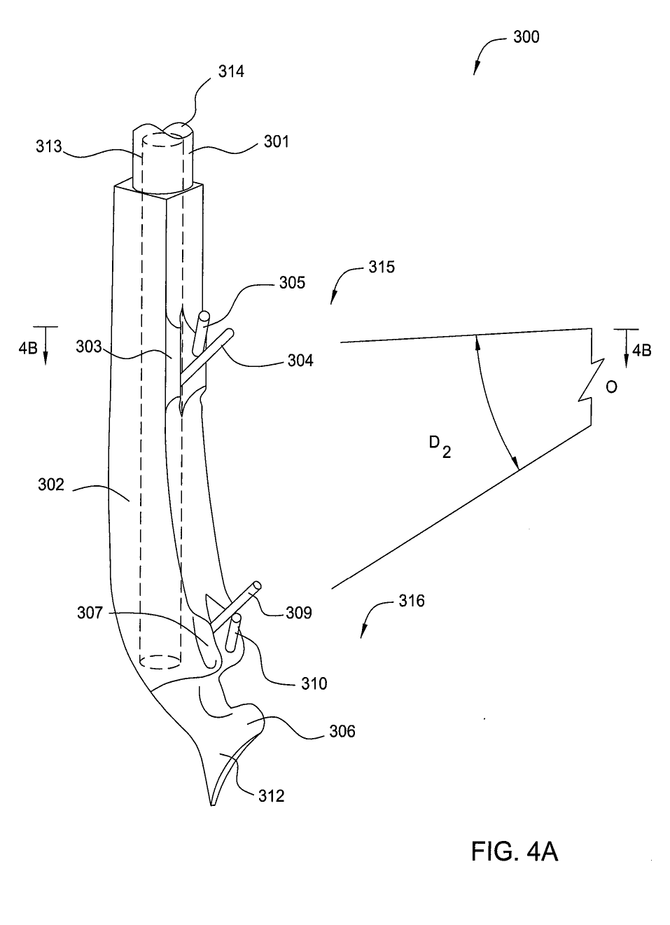

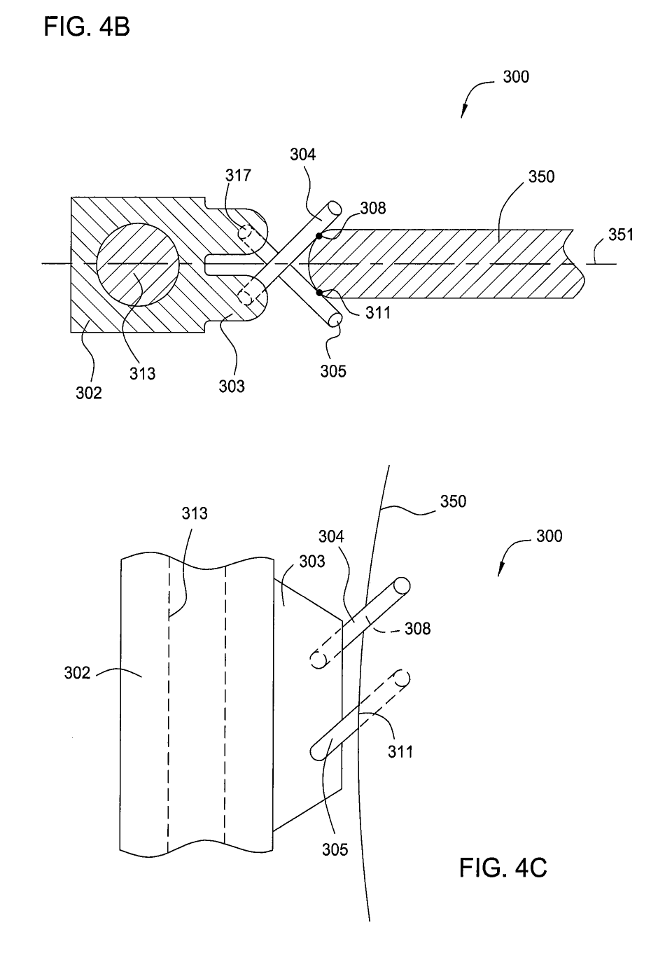

FIGS. 4A-4C illustrate one embodiment of an end effecter 300 having a reduced contact area with a substrate. FIG. 4A illustrates a perspective view of the end effecter 300 in accordance with one embodiment of the present invention. FIG. 4B illustrates a sectional view of the end effecter 300 of FIG. 4A. FIG. 4C illustrates a partial side view of the end effecter 300 of FIG. 4A. The end effect 300 may be used in pairs for receiving, supporting and transferring a substrate in a substrate processing system, such as the substrate processing system 100 shown in FIGS. 1 and 2.

The end effecter 300 generally comprises a post 301 configured to connect with a substrate transferring mechanism, such as the substrate transfer assembly 102 of the substrate processing system 100. The post 301 may comprise a core 313 made of a rigid material for support and a non-reactive coating 314 protecting the core 313 from processing fluid and vapor. In one embodiment, the core 313 may be made from tungsten carbide (WC) and the non-reactive coating 314 may be made from a polymer, such as perfluoroalkoxy (PFA).

A body 302 is formed on an end of the core 313. The core 313 provides rigid support to the body 302. In one embodiment, a hole may be machined with in the body 302 along nearly the entire length of the body 302 for accommodating the core 313 therein. Two sets of contact assemblies 315 and 316 configured to receive and support a substrate 350 (shown in FIGS. 4B and 4C) are formed on the body 302. In one embodiment, the body 302 may have a pointy end 312 near the bottom facilitating dripping of processing fluid. The body 302 may be made from a material resistive to processing fluids and vapors that may be used in the substrate processing system.

The body 302 may have a slightly curved shape and have two bases 303 and 307 formed on one side. In one embodiment, the bases 303 and 307 are positioned such that an angle D2 formed between the bases 303 and 307 with a vertex at the center O of a substrate being processed is about 20°. The contact assemblies 315 and 316 are formed on the bases 303 and 307 respectively.

The contact assembly 315 comprises rod members 304 and 305 extending from the base 303. As shown in FIG. 4B, the rod members 304 and 305 are secured in holes 317 formed in the base 303. The holes 317 are positioned on opposite sides of the substrate 350 being processed. The rod members 304 and 305 are oriented in a crossing manner, but do not contact each other. The rod member 304 forms about a 45° with a central plane 351 of the body 302 parallel to the substrate 350 and the rod member 305 forms about a 45° with the central plane 351. Referring to FIG. 4C, the rod member 304 forms about a 45° with a radius of the substrate 350 passing the base 303. The rod member 305 forms about the same angle as the rod member 304 with the radius of the substrate 350 passing the base 303.

During operation, the substrate 350 contacts the rod member 304 near a point 308 and the rod member 305 near a point 311. The rod members 304 and 305 provide lateral and radial support to the substrate 350.

Similarly, the contact assembly 316 comprises rod members 309 and 310 extending from the base 307. The rod members 309 and 310 are secured in holes formed in opposite sides of the base 307. The rod members 309 and 310 are oriented in a cross manner but do not contact each other. The rod members 309 and 310 also form similar compound angles with the substrate as the rod members 304 and 305. Each of the rod members 309 and 310 provides lateral and radial support to the substrate 350 on a point.

The body 302 and the rod members 304, 305, 309 and 310 may be made from material that is resistive to processing liquids and vapors, does not scratch the substrate being processed, and good particle performance. Since the rod members 304, 305, 309 and 310 provides lateral and radial support to the substrate 350, it is desirable for the rod members 304, 305, 309 and 310 to be strong enough to support the weight of the substrate 350. In one embodiment, the body 302 may be made from a polymer, such as PFA or TEFLON® polymer. In one embodiment, the rod members 304, 305, 309 and 310 may be made from nitinol wire coated with PTFE. In one embodiment, the rod members 304, 305, 309 and 310 may have a diameter of about 0.062 inch.

In one embodiment, the end effecter 300 may have an appendix support 306 formed near the end of the body 302. The appendix support 306 may provide additional vertical support and/or guide to the substrate 350 reducing burdens on the rod members 304, 305, 309 and 310.

While the foregoing is directed to embodiments of the present invention, other and further embodiments of the invention may be devised without departing from the basic scope thereof, and the scope thereof is determined by the claims that follow.

1. An apparatus for processing a substrate, comprising:
a chamber having an upper opening, a lower process volume and an upper process volume, wherein the lower process volume is configured to retain a processing fluid;
a transfer assembly configured to transfer the substrate in and out the chamber through the upper opening; and
a gas delivery assembly disposed outside the chamber near the upper opening.

2. The apparatus of claim 1, further comprising one or more megasonic transducers disposed in the chamber, wherein the one or more megasonic transducers are configured to direct megasonic energy towards the processing liquid retained in the chamber.

3. The apparatus of claim 1, wherein the transfer assembly comprises:
a frame connected with an actuator configured to move the transfer assembly;
two posts extending from the frame; and
an end effecter formed on an end of each of the two posts, wherein the end effecter configured to receive and support the substrate near a bevel edge.

4. The apparatus of claim 3, wherein the gas delivery assembly comprises a gas nozzle configured to direct a gas towards contact areas between the end effecters and the substrate.

5. The apparatus of claim 4, wherein each of the gas nozzle has a blade shape.

6. The apparatus of claim 3, wherein the gas delivery assembly comprises:
a first pair of gas nozzles positioned on one side of the upper opening; and
a second pair of gas nozzles positioned on an opposite side of the upper opening relative to the first pair of gas nozzles, wherein each of the gas nozzles is configured to direct a gas towards a path of contact areas between the end effecters and the substrate.

7. The apparatus of claim 6, wherein each of the first and second pair of gas nozzles has a blade shape.

8. The apparatus of claim 6, wherein the first pair of gas nozzles are in fluid communication with one another and the second pair of gas nozzles are in fluid communication with one another.

9. The apparatus of claim 3, wherein each of the end effecter comprises two contact assemblies configured to provide lateral and radial support to the substrate.

10. An apparatus for processing a substrate, comprising:
a vertical immersing chamber having an upper opening configured to retain a processing liquid therein;
a transfer assembly configured to transfer the substrate in and out the vertical immersing chamber through the upper opening, the transfer assembly having one or more substrate receiving areas; and
a gas delivery assembly positioned adjacent the upper opening and configured to direct a gas flow towards the substrate receiving areas of the transfer assembly.

11. The apparatus of claim 10, wherein the gas delivery assembly comprises:
a first pair of gas nozzles positioned on one side of the upper opening; and
a second pair of gas nozzles positioned on an opposite side of the upper opening relative to the first pair of gas nozzles, wherein each of the gas nozzles is configured to direct the gas flow towards a path of contact areas between the transfer assembly and the substrate.

12. The apparatus of claim 10, wherein the transfer assembly comprises:
a frame connected with an actuator configured to move the transfer assembly;
two posts extending from the frame; and
an end effecter formed on an end of each of the two posts, wherein the end effecter configured to receive and support the substrate near a bevel edge.

13. A method for processing a substrate, comprising:
introducing the substrate into a chamber through an upper opening of the chamber using a transfer assembly, wherein the chamber retains a processing liquid in a lower processing volume;
immersing the substrate to the processing liquid;
removing the substrate from the chamber using the transfer assembly; and
exposing the substrate to a gas flow delivered from a nozzle positioned outside the chamber near the upper opening.

14. The method of claim 13, wherein immersing the substrate to the processing liquid comprises exposing the substrate to megasonic energy.

15. The method of claim 13, wherein exposing the substrate to the gas comprises delivering the gas flow using one or more nozzles directed to contact areas between the substrate and the transfer assembly.

16. The method of claim 13, wherein the gas flow comprises nitrogen.

17. The method of claim 13, wherein the gas flow comprises a heated gas.

18. A method for processing a substrate, comprising:
introducing the substrate into a chamber through an upper opening of the chamber using a transfer assembly having an end effecter configured to support and receive the substrate, wherein the chamber retains a processing liquid in a lower processing volume;
immersing the substrate to the processing liquid;
removing the substrate from the chamber using the transfer assembly; and
exposing the substrate to a gas flow delivered from a nozzle positioned near a path of the end effecter.

19. The method of claim 18, wherein the nozzle is positioned outside the chamber.

20. The method of claim 18, wherein the nozzle is positioned inside the chamber near the upper opening.
